(19) United States
(12) Patent Application Publication
(10) Pub. No.: US 2013/0162938 A1
(43) Pub. Date: Jun. 27, 2013

(54) Liquid Crystal Display Device, Low Temperature Poly-Silicon Display Device, and Manufacturing Method Thereof

(71) Applicant: Xiu-Feng Zhou, Shenzhen City (CN)

(72) Inventor: Xiu-Feng Zhou, Shenzhen City (CN)

(73) Assignee: SHENZHEN CHINA STAR OPTOELECTRONICS TECHNOLOGY CO., LTD., Shenzhen City, Guangdong (CN)

(21) Appl. No.: 13/499,683

(22) PCT Filed: Feb. 16, 2012
(86) PCT No.: PCT/CN12/71187

§ 371 Date: May 9, 2012

(30) Foreign Application Priority Data
Dec. 21, 2011 (CN) 201110433181.3

(51) Int. Cl. G02F 1/1343; H01L 29/16; H01L 33/02

(52) U.S. Cl. 349/139; 438/34; 257/49; 257/E33.003; 257/E29.082

(57) ABSTRACT

The present invention discloses a liquid crystal display device, a low temperature poly-silicon display device, and a manufacturing method thereof. The manufacturing method includes: forming a metal shield layer on a substrate; forming a poly-silicon layer above the metal shield layer and insulated from the metal shield layer; and forming a common electrode and a pixel electrode layer above the poly-silicon layer to be insulated from each other to have the pixel electrode layer electrically connected to the poly-silicon layer and the common electrode electrically connected to the metal shield layer. Through the above described method, the present invention reduces the resistance of the common electrode, reduces the delay effect caused by excessively large electrical resistance of the common electrode, reduces the number of masking operation by one, reduces the period of time by which a manufacturing process is completed, lowers down the cost, and increases the throughput.

### BACKGROUND OF THE INVENTION

1. Field of the Invention

The present invention relates to the field of displaying techniques, and in particular to a liquid crystal display device, a low temperature poly-silicon display device, and a manufacturing method thereof.

2. The Related Arts

Low temperature poly-silicon techniques have been widely applied to liquid crystal display devices and/or organic light-emitting diodes by being used in combination with IPS (In-Plane Switching) or FFS (Fringe Field Switching) techniques to provide improved displaying characteristics and to better meet the needs of general consumers.

As shown in FIG. 1, conventionally, a low temperature poly-silicon display device comprises: a substrate 10, a metal shield layer 11, a poly-silicon layer 12, a common electrode 13, and a metal layer 14. The metal shield layer 11, the poly-silicon layer 12, the common layer 13, and the metal layer 14 are sequentially formed on the substrate 10, in which a portion of the poly-silicon 12 serves as a channel 15 of thin-film transistor. The purpose of forming the metal shield layer 11 is to reduce leakage current caused by light illumination in order to protect the channel 15 of thin-film transistor. The metal layer 14 is deposited on the common electrode 13 and is connected parallel to the common electrode 13 to provide an effect of reducing the resistance of the common electrode 13 and thus reducing the delay effect caused by excessive electrical resistance of the common electrode 13.

Conventionally, at least 12 times of masking are needed in carrying out a complete manufacturing process including the above discussed process. Such a manufacturing process is expensive and an extended period of time is required to complete the whole process. This severely affects the throughput.

### SUMMARY OF THE INVENTION

The technical issue to be addressed by the present invention is to provide a liquid crystal display device, a low temperature poly-silicon display device, and a manufacturing method thereof.

The resistance of a common electrode layer can be reduced and the delay effect caused by excessively large resistance of the common electrode layer can be reduced. The number of masking operation can be reduced by one. The cost is reduced and the throughput is improved.

To address the above technical issue, the present invention adopts a technical solution by providing a liquid crystal display device, which comprises a substrate, on which a metal shield layer is formed, a poly-silicon layer being formed above the metal shield layer and insulated from the metal shield layer, a common electrode and a pixel electrode layer being formed above the poly-silicon layer to be insulated from each other; wherein the pixel electrode layer is electrically connected to the poly-silicon layer, the metal shield layer extending under and corresponding to the common electrode, the common electrode being electrically connected to the metal shield layer.

Wherein, the low temperature poly-silicon display device comprises three insulation layers arranged on the poly-silicon layer, a first conductive path being formed at a site of electrical connection between the poly-silicon layer and the pixel electrode layer to extend through the three insulation layers, a second conductive path being formed at a site of electrical connection between the metal shield layer the common electrode to extend through the three insulation layers; and the pixel electrode layer is electrically connected to the poly-silicon layer through the first conductive path and the common electrode is electrically connected to the metal shield layer through the second conductive path.

Wherein, the liquid crystal display device is an in-plane Switching (IPS) or fringe field switching (FFS) liquid crystal display device.

To address the above technical issue, the present invention adopts another technical solution by providing a method for manufacturing low temperature poly-silicon display device, comprising: forming a metal shield layer on a substrate; forming a poly-silicon layer above the metal shield layer and insulated from the metal shield layer; and forming a common electrode and a pixel electrode layer above the poly-silicon layer to be insulated from each other to have the pixel electrode layer electrically connected to the poly-silicon layer and the common electrode electrically connected to the metal shield layer.

Wherein, the step of forming a metal shield layer on a substrate comprises: forming the metal shield layer on the substrate so that the metal shield layer extends under and corresponds to the common electrode.

Wherein, the step of forming a common electrode and a pixel electrode layer above the poly-silicon layer to be insulated from each other to have the pixel electrode layer electrically connected to the poly-silicon layer and the common electrode electrically connected to the metal shield layer comprises: sequentially forming three insulation layers above the poly-silicon layer, in which a first conductive path is formed at a site of electrical connection between the poly-silicon layer and the pixel electrode layer to extend through the three insulation layers and a second conductive path is formed at a site of electrical connection between the metal shield layer the common electrode to extend through the three insulation layers; and forming the common electrode and the pixel electrode layer on the three insulation layers to be insulated from each other and having the pixel electrode layer electrically connected to the poly-silicon layer through the first conductive path and having the common electrode electrically connected to the metal shield layer through the second conductive path.

Wherein, the step of sequentially forming three insulation layers above the poly-silicon layer, in which a first conductive path is formed at a site of electrical connection between the poly-silicon layer and the pixel electrode layer to extend through the three insulation layers and a second conductive path is formed at a site of electrical connection between the metal shield layer the common electrode to extend through the three insulation layers, comprises: sequentially forming two of the three insulation layers on the poly-silicon layer; forming a first through hole in said two insulation layers at a site of electrical connection between the poly-silicon layer and the pixel electrode layer; filling a first conductive material in the first through hole; forming the remaining one of the three insulation layers on said two insulation layers after the first through hole is filled with the first conductive material; forming a second through hole in said remaining one of the three insulation layers at a site of electrical connection between the poly-silicon layer and the pixel electrode layer, and forming a third through hole extending through the three insulation layers at a site of electrical connection between the metal shield layer and the common electrode; and filling a second conductive material in the second through hole, the first conductive material being connected to the second conductive material to form the first conductive path, and filling a third conductive material in the third through hole to form the second conductive path.

To address the above technical issue, the present invention adopts a further technical solution by providing a low temperature poly-silicon display device, characterized by comprising: a substrate, on which a metal shield layer is formed, a poly-silicon layer being formed above the metal shield layer and insulated from the metal shield layer, a common electrode and a pixel electrode layer being formed above the poly-silicon layer to be insulated from each other; wherein the pixel electrode layer is electrically connected to the poly-silicon layer and the common electrode is electrically connected to the metal shield layer.

Wherein, the metal shield layer extends under and corresponds to the common electrode to be electrically connected to the common electrode.

Wherein, the low temperature poly-silicon display device comprises three insulation layers arranged on the poly-silicon layer, a first conductive path being formed at a site of electrical connection between the poly-silicon layer and the pixel electrode layer to extend through the three insulation layers, a second conductive path being formed at a site of electrical connection between the metal shield layer the common electrode to extend through the three insulation layers; and the pixel electrode layer is electrically connected to the poly-silicon layer through the first conductive path and the common electrode is electrically connected to the metal shield layer through the second conductive path.

Wherein, the low temperature poly-silicon display device is a liquid crystal display device.

Wherein, the liquid crystal display device is an in-plane Switching (IPS) or fringe field switching (FFS) liquid crystal display device.

Wherein, the low temperature poly-silicon display device is an organic light-emitting diode display device.

The efficacy of the present invention is that to be distinguished from the state of the art, the present invention realizes reduction of the resistance of the common electrode and alleviation the delay effect caused by excessively large electrical resistance of the common electrode by providing electrical connection of the common electrode to an existing metal shield layer, so that there is no need to specifically form a metal layer that is made in parallel connection with the common electrode in order to reduce the electrical resistance of the common electrode, whereby the number of application of mask is reduced by one and the period of time with which a complete manufacturing process is done can be reduced to lower down the cost and improve the throughput.

### BRIEF DESCRIPTION OF THE DRAWINGS

FIG. 1 is a partial cross-sectional view of a thin-film transistor substrate of an embodiment of conventional low temperature poly-silicon display device;

FIG. 2 is a partial cross-sectional view of a thin-film transistor substrate of low temperature poly-silicon display device according to an embodiment of the present invention; and

FIG. 3 is a flow chart showing a method for manufacturing a low temperature poly-silicon display device according to the present invention.

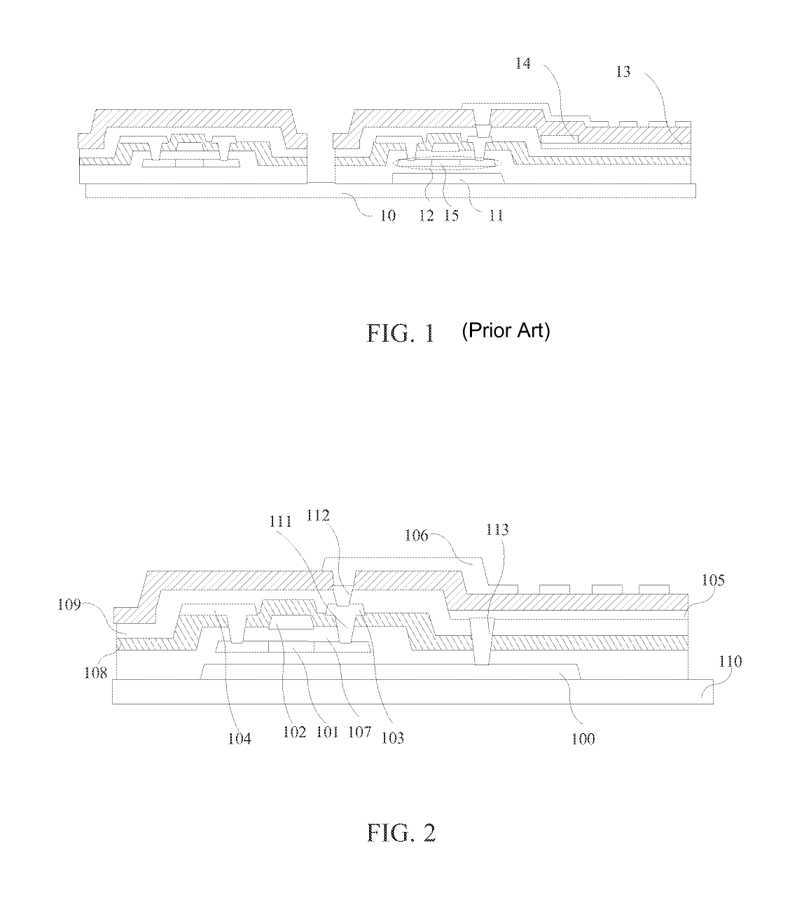

### DETAILED DESCRIPTION OF THE PREFERRED EMBODIMENTS

A detailed description of a low temperature poly-silicon display device according to an embodiment of the present invention will be given in order to more clearly disclose specifics and spirit of the present invention.

Referring to FIG. 2, FIG. 2 is a partial cross-sectional view of a thin-film transistor substrate of low temperature poly-silicon display device according to an embodiment of the present invention. The low temperature poly-silicon display device comprises:
a substrate 110, a metal shield layer 100, a poly-silicon layer 101, a gate metal layer 102, a source metal layer 103, a drain metal layer 104, a common electrode 105, and a pixel electrode layer 106.

The metal shield layer 100 is arranged on the substrate 110 to reduce leakage current caused by light illumination.

The poly-silicon layer 101 is formed above the metal shield layer 100 and is insulated from the metal shield layer 100. The gate metal layer 102 is arranged above the poly-silicon layer 101 and is insulated by the first insulation layer 107 from the poly-silicon layer 101. The source metal layer 103 and the drain metal layer 104 are formed on the same metal layer and are both arranged above the gate metal layer 102 and are insulated by the second insulation layer 108 from the gate metal layer 102. The common electrode 105 is arranged above the source metal layer 103 and is insulated by the third insulation layer 109 from the source metal layer 103. The common electrode 105 can be a transparent conductive film, such as ITO or other transparent conductive material, such as transparent metals. The metal shield layer 100 extends under and corresponding to the common electrode 105 to allow the metal shield layer 100 to be electrically connected to the common electrode 105.

The poly-silicon layer 101 serves as conductive channel of the thin-film transistor and is connected to both the source metal layer 103 and the drain metal layer 104. The gate metal layer 102, the source metal layer 103, and the drain metal layer 104 collectively constitute the thin-film transistor or an organic light-emitting diode. By using the thin-film transistor to control the pixel electrode layer 106 to generate an electrical field or not and how to generate the electrical field, displaying can be realized. Or alternatively, in other embodiments, by controlling the organic light-emitting diode to emit light or not and how to emit light, displaying can be realized.

The pixel electrode layer 106 is arranged above the common electrode 105 and is insulated from the common electrode 105. The common electrode 105 may receive a metal layer disposed thereon in order to further reduce the electrical resistance of the common electrode 105. Of course, the common electrode 105 may receive no such a metal layer thereon. The pixel electrode layer 106 is formed in a displaying area of the low temperature poly-silicon display device. The pixel electrode layer 106 is made of a transparent conductive film, such as ITO.

The first insulation layer 107 and the second insulation layer 108 that are located above the poly-silicon layer 101 form a first through hole 111. The first through hole 111 extends through the first insulation layer 107 and the second insulation layer 108 and is filled up with the same conductive material as the source metal layer 103. The source metal layer 103 is electrically connected, through the first through hole 111, to the poly-silicon layer 101.

The third insulation layer 109 that is located above the source metal layer 103 forms second through hole 112. The second through hole 112 extends through the third insulation layer 109 and is filled up with the same conductive material as the pixel electrode 106. The pixel electrode layer 106 is electrically connected, through the second through hole 112, to the source metal layer 103.

The first through hole 111 and the second through hole 112 collectively define a first conductive path. The pixel electrode layer 106 is electrically connected, via the first conductive path, to the poly-silicon layer 101.

In forming the first conductive path, an alternative way is to form a through hole directly extending between the pixel electrode layer 106 and the poly-silicon layer 101 in order to establish electrical connection between the pixel electrode layer 106 and the poly-silicon layer 101.

Alternatively, in forming the first conductive path, after the first through hole 111 and the second through hole 112 are formed, a through hole may be formed to extend between the pixel electrode 106 and the common electrode 105 in order to establish electrical connection between the pixel electrode layer 106 and the poly-silicon layer 101.

A third through hole 113 is formed above the metal shield layer 100. The third through hole 113 extends through the first insulation layer 107 and the second insulation layer 108 between the common electrode 105 and the metal shield layer 100 and is filled up with the same conductive material as that of the common electrode 105. The common electrode 105 is electrically connected, through the third through hole 113, to the metal shield layer 100.

The third through hole 113 serves as a second conductive path, which realizes electrical connection between the common electrode 105 and the metal shield layer 100. The third through hole 113 can be formed in the same masking operation as that of the first through hole 111. The third through hole 113 may be of a number of one or more than one to provide improved electrical connection between the common electrode 105 and the metal shield layer 100.

The above described structure and type of the low temperature poly-silicon display device are only illustrative and the invention is applicable to various types of liquid crystal display device, such as TN, STN, IPS, or FFS thin-film transistor. Or, it can be an organic light-emitting diode display device. The disclosure imposes no constraint in this respect.

To be distinguished from the state of the art, the present invention realizes reduction of the resistance of the common electrode and alleviation the delay effect caused by excessively large electrical resistance of the common electrode by providing electrical connection of the common electrode to an existing metal shield layer, so that there is no need to specifically form a metal layer that is made in parallel connection with the common electrode in order to reduce the electrical resistance of the common electrode, whereby the number of application of mask is reduced by one and the period of time with which a complete manufacturing process is done can be reduced to lower down the cost and improve the throughput.

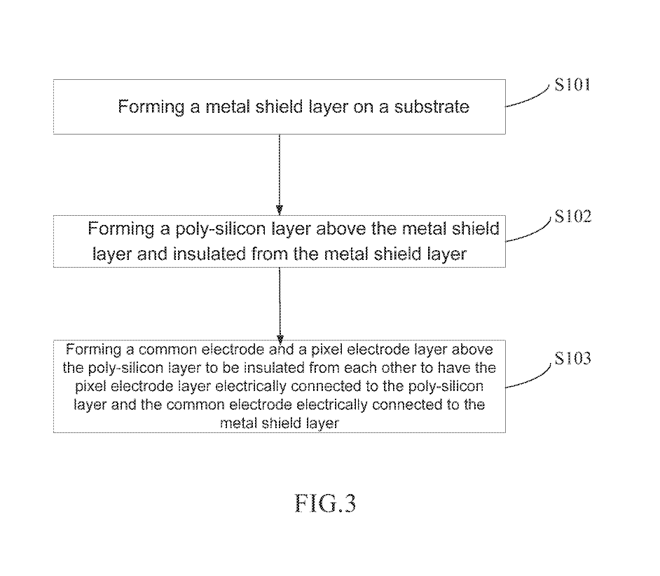

As shown in FIG. 3, FIG. 3 is a flow chart showing a method for manufacturing a low temperature poly-silicon display device according to the present invention. The method for manufacturing a low temperature poly-silicon display device comprises the following steps:

Step S101: forming a metal shield layer on a substrate;

Step S102: forming a poly-silicon layer above the metal shield layer and insulated from the metal shield layer; and

Step S103: forming a common electrode and a pixel electrode layer above the poly-silicon layer to be insulated from each other to have the pixel electrode layer electrically connected to the poly-silicon layer and the common electrode electrically connected to the metal shield layer.

Further referring to FIG. 2, in conducting Step S101 the metal shield layer 100 is made extending under and corresponding to the common electrode 105 to allow the metal shield layer 100 to be electrically connected to the common electrode 105.

Further referring to FIG. 2, in conducting Step S102, a first insulation layer 107, a gate metal layer 102, a second insulation layer 108, a source metal layer 104, and a third insulation layer 109 are sequentially deposited on the poly-silicon layer 101.

A first through hole 111 is formed above the poly-silicon layer 100 in such a way that the first through hole 111 extends through the first insulation layer 107 and the second insulation layer 108 and the first through hole 111 is filled up with the same conductive material as that of the source metal layer 104. The source metal layer 104 is electrically connected, through the first through hole 111, to the poly-silicon layer 101. A second through hole 112 is formed above the source metal layer 104 in such a way that the second through hole 112 extends through the third insulation layer 109 and the second through hole 112 is filled up with the same conductive material as that of the pixel electrode layer 106. The pixel electrode layer 106 is electrically connected, through the second through hole 112, to the source metal layer 104. The first through hole 111 and the second through hole 112 collectively define a first conductive path, and the pixel electrode layer 106 is electrically connected, through the first conductive path, to the poly-silicon layer 100.

Further referring to FIG. 2, in conducting Step S103, the common electrode 105 and the pixel electrode layer 106 are sequentially formed on the third insulation layer 109.

A third through hole 113 is formed above the metal shield layer 100 in such a way that the third through hole 113 extends through the first insulation layer 107 and the second insulation layer 108 between the common electrode 105 and the metal shield layer 100 and the third through hole 113 is filled up with the same conductive material as that of the common electrode 105. The common electrode 105 is electrically connected, through the third through hole 113, to the metal shield layer 100. The third through hole 113 serves as a second conductive path that provides electrical connection between the common electrode 105 and the metal shield layer 100. The third through hole 113 and the first through hole 111 are formed in the same masking process. The third through hole 113 can be of a number of one or more than one to provide improved electrical connection between the common electrode 105 and the metal shield layer 100.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A liquid crystal display device, comprising:
a substrate, on which a metal shield layer is formed, a poly-silicon layer being formed above the metal shield layer and insulated from the metal shield layer, a common electrode and a pixel electrode layer being formed above the poly-silicon layer to be insulated from each other;
wherein the pixel electrode layer is electrically connected to the poly-silicon layer, the metal shield layer extending under and corresponding to the common electrode, the common electrode being electrically connected to the metal shield layer.

2. The liquid crystal display device as claimed in claim 1, wherein:
the low temperature poly-silicon display device comprises three insulation layers arranged on the poly-silicon layer, a first conductive path being formed at a site of electrical connection between the poly-silicon layer and the pixel electrode layer to extend through the three insulation layers, a second conductive path being formed at a site of electrical connection between the metal shield layer the common electrode to extend through the three insulation layers; and
the pixel electrode layer is electrically connected to the poly-silicon layer through the first conductive path and the common electrode is electrically connected to the metal shield layer through the second conductive path.

3. The liquid crystal display device as claimed in claim 1, wherein:
the liquid crystal display device is an in-plane Switching (IPS) or fringe field switching (FFS) liquid crystal display device.

4. A method for manufacturing low temperature poly-silicon display device, comprising the following steps:
forming a metal shield layer on a substrate;
forming a poly-silicon layer above the metal shield layer and insulated from the metal shield layer; and
forming a common electrode and a pixel electrode layer above the poly-silicon layer to be insulated from each other to have the pixel electrode layer electrically connected to the poly-silicon layer and the common electrode electrically connected to the metal shield layer.

5. The method as claimed in claim 4, wherein:
the step of forming a metal shield layer on a substrate comprises: forming the metal shield layer on the substrate so that the metal shield layer extends under and corresponds to the common electrode.

6. The method as claimed in claim 5, wherein:
the step of forming a common electrode and a pixel electrode layer above the poly-silicon layer to be insulated from each other to have the pixel electrode layer electrically connected to the poly-silicon layer and the common electrode electrically connected to the metal shield layer comprises:
sequentially forming three insulation layers above the poly-silicon layer, in which a first conductive path is formed at a site of electrical connection between the poly-silicon layer and the pixel electrode layer to extend through the three insulation layers and a second conductive path is formed at a site of electrical connection between the metal shield layer the common electrode to extend through the three insulation layers; and
forming the common electrode and the pixel electrode layer on the three insulation layers to be insulated from each other and having the pixel electrode layer electrically connected to the poly-silicon layer through the first conductive path and having the common electrode electrically connected to the metal shield layer through the second conductive path.

7. The method as claimed in claim 6, wherein:
the step of sequentially forming three insulation layers above the poly-silicon layer, in which a first conductive path is formed at a site of electrical connection between the poly-silicon layer and the pixel electrode layer to extend through the three insulation layers and a second conductive path is formed at a site of electrical connection between the metal shield layer the common electrode to extend through the three insulation layers, comprises:
sequentially forming two of the three insulation layers on the poly-silicon layer;
forming a first through hole in said two insulation layers at a site of electrical connection between the poly-silicon layer and the pixel electrode layer;
filling a first conductive material in the first through hole;
forming the remaining one of the three insulation layers on said two insulation layers after the first through hole is filled with the first conductive material;
forming a second through hole in said remaining one of the three insulation layers at a site of electrical connection between the poly-silicon layer and the pixel electrode layer, and forming a third through hole extending through the three insulation layers at a site of electrical connection between the metal shield layer and the common electrode; and
filling a second conductive material in the second through hole, the first conductive material being connected to the second conductive material to form the first conductive path, and filling a third conductive material in the third through hole to form the second conductive path.

8. A low temperature poly-silicon display device, comprising:
a substrate, on which a metal shield layer is formed, a poly-silicon layer being formed above the metal shield layer and insulated from the metal shield layer, a common electrode and a pixel electrode layer being formed above the poly-silicon layer to be insulated from each other;
wherein the pixel electrode layer is electrically connected to the poly-silicon layer and the common electrode is electrically connected to the metal shield layer.

9. The low temperature poly-silicon display device as claimed in claim 8, wherein:
the metal shield layer extends under and corresponds to the common electrode to be electrically connected to the common electrode.

10. The low temperature poly-silicon display device as claimed in claim 9, wherein:
the low temperature poly-silicon display device comprises three insulation layers arranged on the poly-silicon layer, a first conductive path being formed at a site of electrical connection between the poly-silicon layer and the pixel electrode layer to extend through the three insulation layers, a second conductive path being formed at a site of electrical connection between the metal shield layer the common electrode to extend through the three insulation layers; and
the pixel electrode layer is electrically connected to the poly-silicon layer through the first conductive path and the common electrode is electrically connected to the metal shield layer through the second conductive path.

11. The low temperature poly-silicon display device as claimed in claim 8, wherein:
the low temperature poly-silicon display device is a liquid crystal display device.

12. The low temperature poly-silicon display device as claimed in claim 11, wherein:
the liquid crystal display device is an in-plane Switching (IPS) or fringe field switching (FFS) liquid crystal display device.

13. The low temperature poly-silicon display device as claimed in claim 8, wherein:
the low temperature poly-silicon display device is an organic light-emitting diode display device.
